(19) United States
(12) Patent Application Publication
(10) Pub. No.: US 2026/0020389 A1
(43) Pub. Date: Jan. 15, 2026

(54) SEMICONDUCTOR STRUCTURE AND MANUFACTURING METHOD THEREOF

(71) Applicant: Taiwan-Asia Semiconductor Corporation, Hsinchu City (TW)

(72) Inventors: Wen-Hsiang Lin, Hsinchu City (TW); Shih-Min Wu, Hsinchu City (TW); Hsuan-Ting Chang, Hsinchu City (TW); Wang-Cheng Hsu, Hsinchu City (TW)

(21) Appl. No.: 18/978,546

(22) Filed: Dec. 12, 2024

(30) Foreign Application Priority Data
Jul. 15, 2024 (TW) 113126416

(51) Int. Cl. H10H 20/832; H10H 20/01; H10H 20/824

(52) U.S. Cl. CPC H10H 20/832; H10H 20/032; H10H 20/824

(57) ABSTRACT

A semiconductor structure and a manufacturing method thereof are provided. The semiconductor structure includes a substrate, a semiconductor composite layer and a metal electrode structure. The semiconductor composite layer is disposed on the substrate, and the metal electrode structure is disposed on the semiconductor composite layer, which includes a metal pad layer, a metal barrier layer and a metal stack. The metal barrier layer has a specific thickness to prevent the metal stack from breaking through the metal barrier layer and diffusing to the metal pad layer during a heating process.

### CROSS-REFERENCES TO RELATED APPLICATIONS

This application claims the benefit of priority to Taiwanese Patent Application No. 113126416 filed on Jul. 15, 2024, which is hereby incorporated by reference in its entirety.

### BACKGROUND OF THE INVENTION

### Field of the Invention

The present invention relates to a semiconductor structure and a manufacturing method thereof, and in particular to a semiconductor electrode structure and a manufacturing method thereof.

### Descriptions of the Related Art

Regarding III-V compound semiconductors, they have been widely used in products such as light-emitting diodes, high-power devices, gas detection devices, and invisible light detection devices. During the wafer manufacturing processes of these devices, a process in which metal and semiconductor come into contact with each other needs to be handled. According to the physical properties, two types of contacts including a Schottky contact and an ohmic contact will be discussed. In order to achieve the ohmic contact between the metal and semiconductor interface, a thermal process is often used, for example, an alloy processing or a rapid thermal processing (RTP).

Regarding the ohmic contact between the metal layer and the semiconductor layer, the matching of the metal layered design with the specific temperature and gas flow during the alloy process is the key to determining whether its specific contact resistance can meet the ohmic contact requirements. However, if one pursues the ohmic contact between the metal layer and the semiconductor layer, the appearance of the metal electrode after the alloy is completed is often ignored. This appearance morphology is closely related to the stability of the wire bonding of the chips. If the electrodes of the chip produced during the alloy process have abnormal appearance, it will also affect the wire bonding of the package, and the bonding pads may fall off and cause a short circuit of the entire device. In order to overcome the above problems, the industry urgently needs an innovative semiconductor structure and its manufacturing method to effectively improve the stability of the ohmic contact of electrodes and meet the requirements of the chip packaging.

### SUMMARY OF THE INVENTION

The main objective of the present invention is to provide an innovative semiconductor structure and a manufacturing method thereof. By optimizing the metal electrode structure, the metal electrode structure forms inverted triangle alloy marks at the interface with the semiconductor composite layer. These inverted triangle alloy marks enhance the adhesion between the metal electrode structure and the compound semiconductor layers to achieve ohmic contact of the electrode and meet the requirements of the chip packaging.

To achieve the above objective, the present invention discloses a semiconductor structure which includes a substrate, a semiconductor composite layer and a metal electrode structure. The semiconductor composite layer is disposed on the substrate, and the metal electrode structure is disposed on the semiconductor composite layer, which includes a metal pad layer, a metal barrier layer and a metal stack. The metal barrier layer has a specific thickness to prevent the metal stack from breaking through the metal barrier layer and diffusing to the metal pad layer during a heating process.

In one embodiment of the semiconductor structure of the present invention, the material of the metal barrier layer is selected from the group consisting of titanium (Ti), platinum (Pt), silver (Ag), zinc (Zn) and iron (Fe).

In one embodiment of the semiconductor structure of the present invention, the specific thickness of the metal barrier layer is not less than 500 Angstroms (Å).

In one embodiment of the semiconductor structure of the present invention, as the semiconductor composite layer has a P-type III-V compound layer in contact with the metal stack, the metal stack is a stack of gold (Au)/beryllium gold (BeAu)/gold (Au) or a stack of gold (Au)/zinc gold (ZnAu)/gold (Au).

In one embodiment of the semiconductor structure of the present invention, the P-type III-V compound layer is a P-type aluminum gallium arsenide (AlGaAs) layer.

In one embodiment of the semiconductor structure of the present invention, as the semiconductor composite layer has an N-type III-V compound layer in contact with the metal stack, the metal stack is a stack of gold (Au)/germanium gold (GeAu)/gold (Au).

In one embodiment of the semiconductor structure of the present invention, the N-type III-V compound layer is an N-type aluminum gallium arsenide (AlGaAs) layer.

In one embodiment of the semiconductor structure of the present invention, the semiconductor structure further comprises a plurality of inverted triangle alloy marks formed at the interface between the metal stack and the semiconductor composite layer after the heating process.

In one embodiment of the semiconductor structure of the present invention, the metal pad layer is an aluminum layer.

To achieve the above objective, the present invention discloses a manufacturing method of a semiconductor structure, the manufacturing method comprises the following steps: providing a substrate; providing a semiconductor composite layer, disposed on the substrate; providing a metal electrode structure, disposed on the semiconductor composite layer, wherein the step of providing the metal electrode structure includes providing a metal pad layer, a metal barrier layer and a metal stack sequentially on the semiconductor composite layer; and heating the semiconductor structure to form a plurality of inverted triangle alloy marks at the interface between the metal stack and the semiconductor composite layer, wherein the metal barrier layer has a specific thickness to prevent the metal stack from breaking through the metal barrier layer and diffusing to the metal pad layer during the heating process.

In one embodiment of the manufacturing method of the semiconductor structure of the present invention, the step of providing the metal barrier layer is to provide a material selected from the group consisting of titanium (Ti), platinum (Pt), silver (Ag), zinc (Zn) and iron (Fe).

In one embodiment of the manufacturing method of the semiconductor structure of the present invention, the step of providing the metal barrier layer is to provide the metal barrier layer with a specific thickness of no less than 500 Angstroms (Å).

After referring to the drawings and the embodiments as described in the following, those the ordinary skilled in this art can understand other objectives of the present invention, as well as the technical means and embodiments of the present invention.

### BRIEF DESCRIPTION OF THE DRAWINGS

FIG. 1 is a cross-sectional schematic diagram of a light-emitting diode structure according to the present invention;

FIG. 2 is a top view schematic diagram of a light-emitting diode according to the present invention;

FIG. 3 is a front view schematic diagram of a wafer with multiple light-emitting diodes according to the present invention;

FIG. 4 is a schematic diagram of a quartz furnace used in the production of a light-emitting diode according to the present invention;

FIG. 5 is a partial detailed schematic diagram of the metal electrode structure and the semiconductor composite layer in a light-emitting diode according to the present invention;

FIG. 6 to FIG. 9 are SEM schematic diagrams of the interface between the metal electrode structure and the semiconductor composite layer in a light-emitting diode according to the present invention;

FIG. 10(A) is a schematic diagram of abnormal morphology of the aluminum electrode in the metal electrode structure of a light-emitting diode according to the present invention;

FIG. 10(B) is a schematic diagram of normal morphology of the aluminum electrode in the metal electrode structure of a light-emitting diode according to the present invention; and

FIG. 11 is a flow chart of the manufacturing process of a light-emitting diode according to the present invention.

### DETAILED DESCRIPTION OF THE PREFERRED EMBODIMENT

In the following description, the present invention will be explained with reference to various embodiments thereof. These embodiments of the present invention are not intended to limit the present invention to any specific environment, application or particular method for implementations described in these embodiments. Therefore, the description of these embodiments is for illustrative purposes only and is not intended to limit the present invention. It shall be appreciated that, in the following embodiments and the attached drawings, a part of elements not directly related to the present invention may be omitted from the illustration, and dimensional proportions among individual elements and the numbers of each element in the accompanying drawings are provided only for ease of understanding but not to limit the present invention.

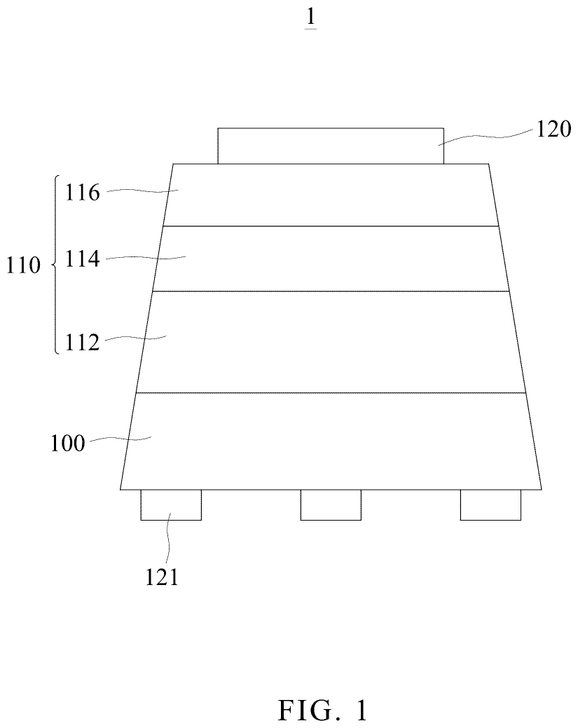

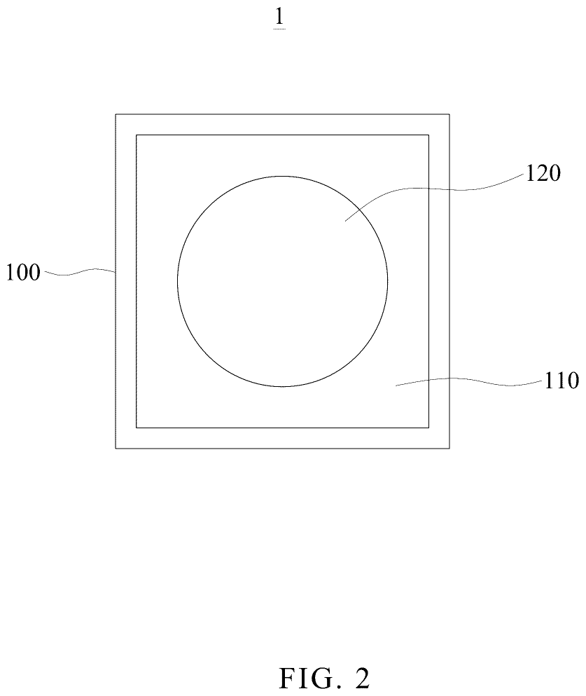

The present invention discloses a semiconductor structure and a manufacturing method thereof, particularly a metal electrode structure in a semiconductor device for achieving ohmic contact at the interface between the metal electrode and the semiconductor layer, while also improving the appearance of the electrode structure to prevent the detachment of bonding pads during subsequent packaging processes. Please refer to FIG. 1 and FIG. 2 together, where FIG. 1 shows a cross-sectional view of a light-emitting diode (LED) 1 according to the present invention, and FIG. 2 shows a top view of an (LED) 1 according to the present invention. The LED 1 of the present invention is sequentially disposed on a substrate 100 with a semiconductor composite layer 110 and a metal electrode structure 120. Additionally, another metal electrode structure 121 is disposed on the other side of the substrate 100. Specifically, the substrate 100 can be, but not limited to, an N-type gallium arsenide (GaAs) substrate. The semiconductor composite layer 110 can include an N-type gallium arsenide (GaAs) layer 112 disposed on the substrate 100, a P-type gallium arsenide (GaAs) epitaxial layer 114 disposed on the N-type gallium arsenide (GaAs) layer 112, and a P-type aluminum gallium arsenide (AlGaAs) epitaxial layer 116 disposed on the P-type gallium arsenide (GaAs) epitaxial layer 114.

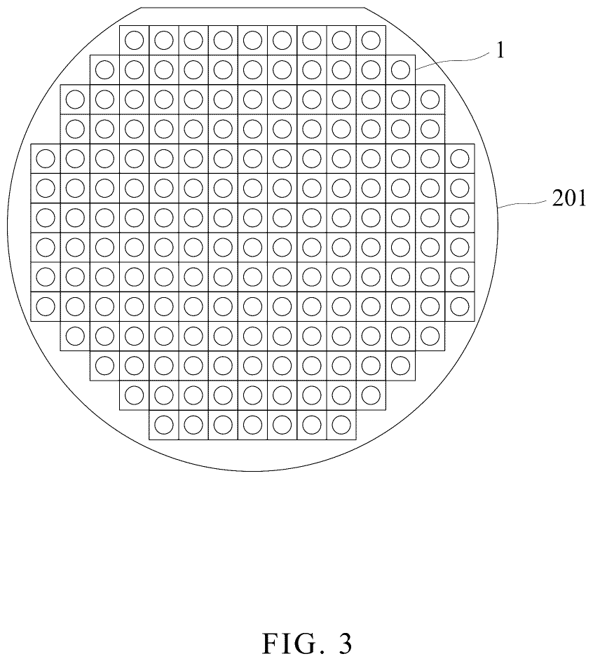

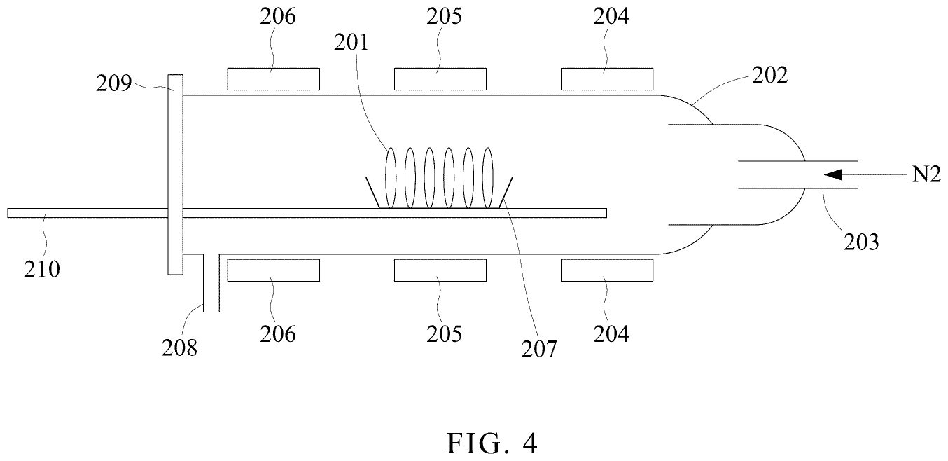

As shown in FIG. 3, it displays a front view of a wafer 201 that can produce multiple units of the light-emitting diode 1 according to the present invention. The wafer 201 has multiple units of LED 1 formed through processes such as semiconductor epitaxy, photolithography, metal evaporation, and chemical etching. Then, the quartz furnace structure shown in FIG. 4 is used to perform the alloying process of the metal electrodes of the LED 1. The quartz furnace structure includes a quartz tube 202, with a nitrogen gas inlet 203 at the source end. The source end, central part, and front end of the quartz furnace 202 are wrapped with coil heaters 204, 205, and 206, respectively. Additionally, the quartz furnace has an exhaust port 208. Before conducting the alloying process, the entire quartz furnace 202 must be preheated using the coil heaters 204, 205, and 206. Appropriate nitrogen gas flow is provided through the inlet 203 for allowing the entire quartz furnace 202 to be uniformly heated for a period. After approximately 1 hour, the wafer 201 can be pushed into the quartz furnace 202 to perform the alloying process.

Please continue to refer to FIG. 4. Multiple wafers 201 are loaded on a wafer boat 207 and introduced into the central part of the quartz furnace 202 using an automated quartz pulling rod 210. At this time, the automatic sealing port 209 of the quartz furnace seals the furnace entrance. After a specific temperature and duration, the automatic sealing port 209 will automatically open, and the quartz pulling rod 210 will automatically and slowly withdraw the wafer boat 207 carrying the wafers 201. Through this process, the ohmic contact between the metal electrode structure 120 and the P-type aluminum gallium arsenide (AlGaAs) epitaxial layer 116 at the interface of each LED unit on the wafer 201 is achieved.

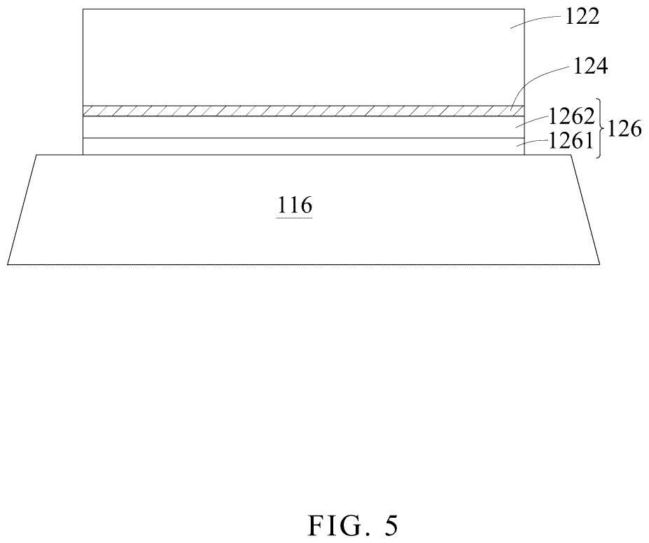

Please refer to FIG. 5, which shows a detailed structural diagram of the metal electrode structure 120 and the P-type aluminum gallium arsenide (AlGaAs) epitaxial layer 116, as indicated in FIG. 2. Specifically, the metal electrode structure 120 is disposed on the semiconductor composite layer 110. The metal electrode structure 120 includes a metal pad layer 122, a metal barrier layer 124, and a metal stack 126. In a specific embodiment, when the semiconductor composite layer 110 has a P-type III-V compound layer, for example, a P-type AlGaAs epitaxial layer 116, a metal stack 126 with a specific thickness is disposed on the P-type AlGaAs epitaxial layer 116. This metal stack 126 can be a gold (Au)/beryllium gold (BeAu) layer 1261. In other embodiments, this Au/BeAu layer 1261 can also be a gold (Au)/zinc gold (ZnAu) layer. Furthermore, another layer of gold (Au) with a specific thickness 1262 is then disposed on the Au/BeAu layer 1261. That is, the metal stack 126 is preferably an Au/BeAu/Au stack or an Au/ZnAu/Au stack. Additionally, in another embodiment, when the semiconductor composite layer has an N-type III-V compound layer in contact with the metal stack, for example, an N-type AlGaAs layer, the metal stack 126 is an Au/germanium gold (GeAu)/Au stack.

Next, a metal barrier layer 124 with a specific thickness is disposed on the metal stack 126. For example, the material of the metal barrier layer 124 is selected from the group consisting of titanium (Ti), platinum (Pt), silver (Ag), zinc (Zn), and iron (Fe). Finally, a layer of aluminum (Al) with a thickness of about 2-4 μm is disposed on the metal barrier layer 124 for serving as the metal pad layer 122 for wire bonding during packaging. In other words, the metal electrode structure 120 in the light-emitting diode 1 of the present invention is preferably a composite layer structure of aluminum (Al)/titanium (Ti)/gold (Au)/beryllium gold (BeAu)/gold (Au), but is not limited thereto.

Taking the metal barrier layer 124 as titanium (Ti) as an example, the following describes different thicknesses of the metal barrier layer, such as 200 Å, 500 Å, 800 Å, and 1600 Å. These different thicknesses are tested by undergoing an alloying process at a specific temperature and for a specific duration in the aforementioned quartz furnace. After the process, the ohmic contact states between the metal electrode structure and the compound semiconductor composite layer of the light-emitting diode structure, as well as the different appearances of the metal electrodes after alloying, are observed. It should be noted that this appearance is closely related to the stability of the wire bonding during the subsequent packaging of the light-emitting diode chips.

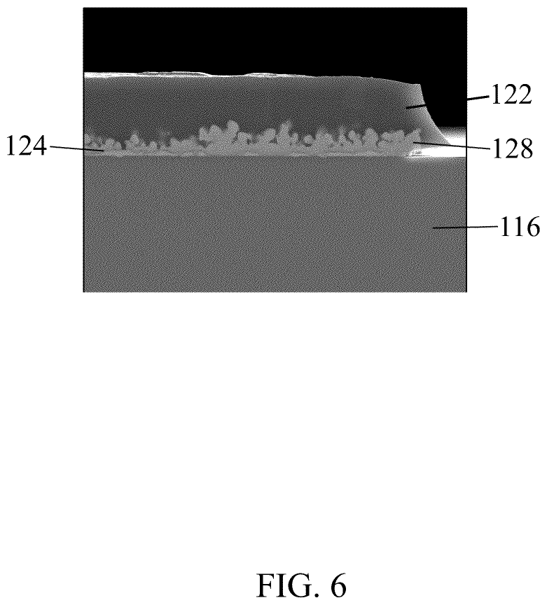

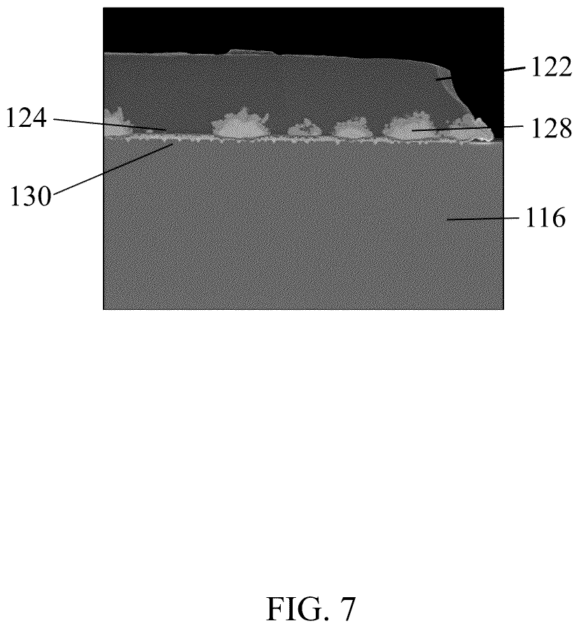

Please refer to FIG. 6 through FIG. 9, which show the SEM images of the alloyed state at the interface between the metal electrode structure and the semiconductor composite layer in the light-emitting diode of the present invention. As shown in FIG. 6, when the thickness of the titanium layer in the metal barrier layer 124 is only 200 Å, it is evident that after the heating process, the metal barrier layer 124 is unable to prevent the underlying metal stack structure from breaking through and forming a diffusion structure 128 that spreads to the top metal pad layer 122. FIG. 7 shows that when the thickness of the titanium layer in the metal barrier layer 124 is increased to 500 Å, the SEM image clearly shows that the diffusion structure 128 is significantly reduced compared to the state shown in FIG. 6. Additionally, it can be observed that after heating and alloying, multiple inverted triangle alloy marks 130 are formed at the interface between the metal stack and the P-type aluminum gallium arsenide (AlGaAs) layer 116 of the semiconductor composite layer 110. The greater the number of these inverted triangle alloy marks, the better the adhesion between the metal electrode structure and the semiconductor composite layer in the light-emitting diode chip, which helps prevent peeling of the metal pad during the packaging process and facilitates ohmic contact at the metal-semiconductor interface.

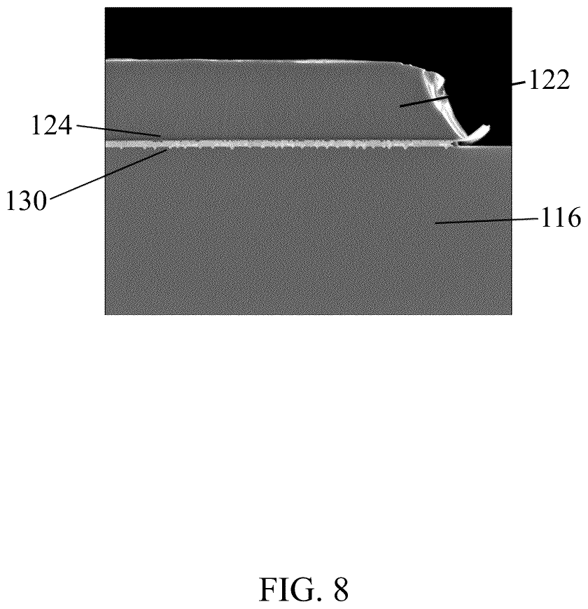

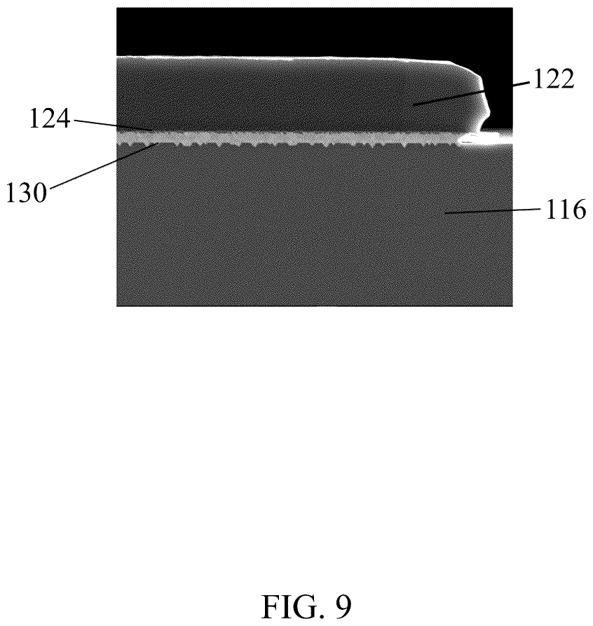

As shown in FIG. 8, when the thickness of the titanium layer in the metal barrier layer 124 is increased to 800 Å, the SEM image reveals that the diffusion structure 128 can no longer be observed. Additionally, the number of inverted triangle alloy marks 130 at the interface between the metal electrode structure and the P-type aluminum gallium arsenide (AlGaAs) layer 116 has substantially increased. FIG. 9 further shows that when the thickness of the titanium layer in the metal barrier layer 124 is increased to 1600 Å, a further optimization can be observed.

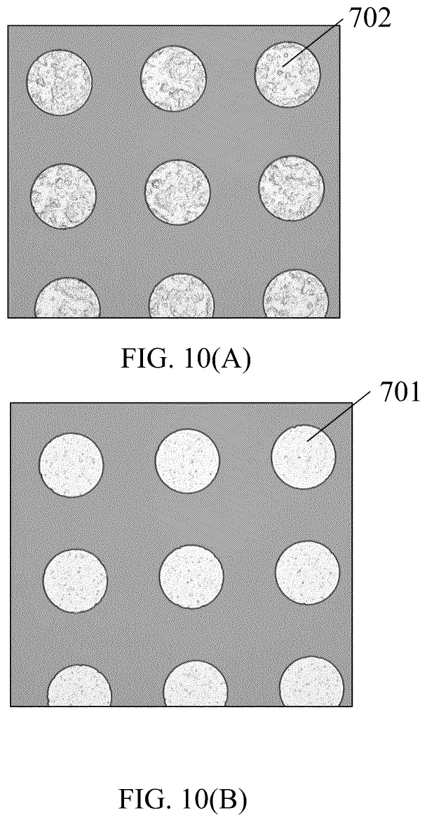

As shown in FIG. 6, when the thickness of the titanium layer in the metal barrier layer 124 is only 200 Å, the SEM image reveals many diffusion structures 128 that break through the metal barrier layer 124 and spread into the metal pad layer 122 after the heating and alloying process. If the extent of diffusion structure 128 is too large, it will directly affect the metal pad layer 122, such as the appearance of the metal aluminum layer. In severe cases, it will lead to abnormal appearances 702 of aluminum electrodes as shown in FIG. 10(A). This abnormal appearance 702 will impact the following wire bonding process during packaging the light-emitting diode. If such abnormal aluminum electrode appearances occur during the wafer processing, the production process will involve removing the metal electrode structure, such as aluminum (Al)/titanium (Ti)/gold (Au)/beryllium-gold (BeAu)/gold (Au), using specific chemical agents and then polishing the surface of the P-type aluminum gallium arsenide layer in the semiconductor composite layer. Afterward, the metal processing of the wafer will be repeated and lead to a decrease in yield and increase production costs and waste.

In contrast, as shown in FIG. 7, when the thickness of the titanium layer in the metal barrier layer 124 is increased to 500 Å, after the heating and alloying process, the SEM image clearly shows that the diffusion structures 128 breaking through the metal barrier layer 124 into the metal pad layer 122 are significantly reduced. Furthermore, many inverted triangle alloy marks 130 are clearly observed, formed as the metal layers are fused towards the P-type aluminum gallium arsenide epitaxial layer 116. The greater the number of these alloy marks, the more they help increase the adhesion between the metal electrode structure and the semiconductor composite layer for reducing the likelihood of peeling of the pads during the following packaging process. In the top view of the chip, a normal appearance of the aluminum metal electrode 701 is observed as shown in FIG. 10(B). This normal appearance 701 ensures that the pads of the light-emitting diode chips are less likely to peel off during the following packaging process.

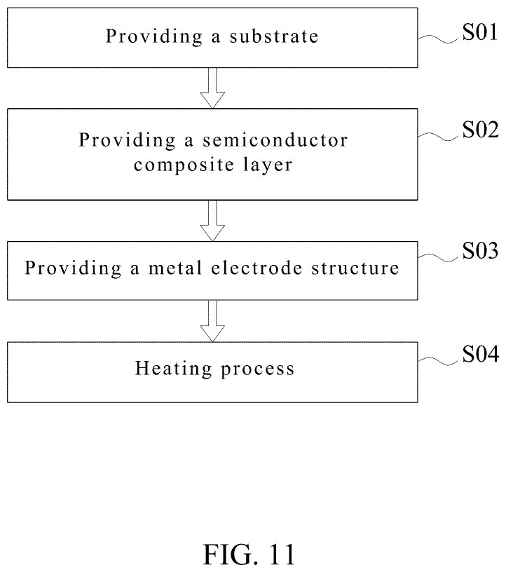

Refer to FIG. 11, which shows the flowchart for manufacturing the semiconductor structure of the present invention. In step S01, a substrate 100 is provided. In step S02, a semiconductor composite layer 110 is formed on the substrate 100. In step S03, a metal electrode structure 120 is formed on the semiconductor composite layer 110. This step includes the step of providing a metal stack 126, a metal barrier layer 124, and a metal pad layer 122 sequentially on the semiconductor composite layer 110. In step S04, the entire semiconductor structure is heated to form multiple inverted triangle alloy marks 130 at the interface between the metal stack 126 and the semiconductor composite layer 110. The metal barrier layer 124 has a specific thickness, for example, greater than 500 Å, to prevent the metal stack 126 from breaking through the metal barrier layer 124 and diffusing into the metal pad layer 122 during the heating step. For detailed explanation, please refer to the aforementioned content, which will not be reiterated here.

In summary, the present invention provides an optimized metal electrode structure and manufacturing method for semiconductor structures. By using a metal barrier layer with a specific thickness, it prevents the metal stack within the metal electrode structure from diffusing into the metal pad surface during the heating process. Thereby, the surface morphology of the metal pad can be preserved and avoid concerns about pad peeling. Additionally, the metal electrode structure forms inverted triangle alloy marks at the interface with the semiconductor composite layer, which enhances the adhesion between the metal electrode structure and the compound semiconductor layer for achieving ohmic contact and meeting the requirements for chip packaging.

The above embodiments are used only to illustrate the implementations of the present invention and to explain the technical features of the present invention, and are not used to limit the scope of the present invention. Any modifications or equivalent arrangements that can be easily accomplished by people skilled in the art are considered to fall within the scope of the present invention, and the scope of the present invention should be limited by the claims of the patent application.

What is claimed is:

1. A semiconductor structure, comprising:
a substrate;
a semiconductor composite layer, disposed on the substrate; and
a metal electrode structure, disposed on the semiconductor composite layer, including a metal pad layer, a metal barrier layer and a metal stack,
wherein the metal barrier layer has a specific thickness to prevent the metal stack from breaking through the metal barrier layer and diffusing to the metal pad layer during a heating process.

2. The semiconductor structure of claim 1, wherein the material of the metal barrier layer is selected from the group consisting of titanium (Ti), platinum (Pt), silver (Ag), zinc (Zn) and iron (Fe).

3. The semiconductor structure of claim 1, wherein the specific thickness of the metal barrier layer is not less than 500 Angstroms (Å).

4. The semiconductor structure of claim 1, wherein as the semiconductor composite layer has a P-type III-V compound layer in contact with the metal stack, the metal stack is a stack of gold (Au)/beryllium gold (BeAu)/gold (Au) or a stack of gold (Au)/zinc gold (ZnAu)/gold (Au).

5. The semiconductor structure of claim 4, wherein the P-type III-V compound layer is a P-type aluminum gallium arsenide (AlGaAs) layer.

6. The semiconductor structure of claim 1, wherein as the semiconductor composite layer has an N-type III-V compound layer in contact with the metal stack, the metal stack is a stack of gold (Au)/germanium gold (GeAu)/gold (Au).

7. The semiconductor structure of claim 6, wherein the N-type III-V compound layer is an N-type aluminum gallium arsenide (AlGaAs) layer.

8. The semiconductor structure of claim 1, further comprising a plurality of inverted triangle alloy marks formed at the interface between the metal stack and the semiconductor composite layer after the heating process.

9. The semiconductor structure of claim 1, wherein the metal pad layer is an aluminum layer.

10. A manufacturing method of a semiconductor structure, comprising:
providing a substrate;
providing a semiconductor composite layer, disposed on the substrate;
providing a metal electrode structure, disposed on the semiconductor composite layer, wherein the step of providing the metal electrode structure includes providing a metal pad layer, a metal barrier layer and a metal stack sequentially on the semiconductor composite layer; and
heating the semiconductor structure to form a plurality of inverted triangle alloy marks at the interface between the metal stack and the semiconductor composite layer,
wherein the metal barrier layer has a specific thickness to prevent the metal stack from breaking through the metal barrier layer and diffusing to the metal pad layer during the heating process.

11. The manufacturing method of claim 10, wherein the step of providing the metal barrier layer is to provide a material selected from the group consisting of titanium (Ti), platinum (Pt), silver (Ag), zinc (Zn) and iron (Fe).

12. The manufacturing method of claim 10, wherein the step of providing the metal barrier layer is to provide the metal barrier layer with a specific thickness of no less than 500 Angstroms (Å).
